(19) United States
(12) Patent Application Publication
(10) Pub. No.: US 2026/0114199 A1
(43) Pub. Date: Apr. 23, 2026

(54) METHOD FOR FABRICATING A SEMICONDUCTOR DEVICE

(71) Applicant: Samsung Electronics Co., Ltd., Suwon-si (KR)

(72) Inventors: Yunsu JANG, Suwon-si (KR); Hironobu ITO, Yokohama-shi (JP); Su Min KIM, Suwon-si (KR); Ye Ji KIM, Suwon-si (KR); Taeseon YUN, Suwon-si (KR); Shinwook YI, Suwon-si (KR); Yukihide TSUJI, Suwon-si (KR)

(73) Assignee: Samsung Electronics Co., Ltd., Suwon-si (KR)

(21) Appl. No.: 19/238,865

(22) Filed: Jun. 16, 2025

(30) Foreign Application Priority Data
Oct. 23, 2024 (KR) 10-2024-0145623

(51) Int. Cl. H01L 21/308; H01L 21/027; H01L 21/033

(52) U.S. Cl. CPC H10P 50/694; H10P 50/692; H10P 50/695; H10P 76/2041; H10P 76/405; H10P 76/4085

(57) ABSTRACT

A method for fabricating a semiconductor device includes forming a lower layer including a metal element on an upper surface of a substrate; forming a photoresist layer on an upper surface of the lower layer; forming a first exposure region and a second exposure region by exposing a photoresist layer portion, and a lower layer portion beneath the first exposure region, respectively, and forming a non-exposure region of unexposed photoresist layer; providing electrons from the second exposure region to a portion of the non-exposure region adjacent to a sidewall of the first exposure region; forming a third exposure region by exposing the portion of the non-exposure region, and forming a photoresist pattern including the first and third exposure regions by etching the non-exposure region; wherein an upper surface width of the first exposure region is greater than a bottom surface width of the first exposure region.

### CROSS-REFERENCE TO RELATED APPLICATION

This application claims priority from Korean Patent Application No. 10-2024-0145623, filed on Oct. 23, 2024, in the Korean Intellectual Property Office, and all the benefits accruing therefrom under 35 U.S.C. § 119, the entire contents of which are hereby incorporated by reference.

### TECHNICAL FIELD

Apparatuses and methods consistent with some embodiments of the present disclosure relate to semiconductor device fabrication, and more particularly, to methods of fabricating a semiconductor device using a photoresist pattern.

### BACKGROUND

With the advancement of the electronics industry, the demand for higher functionality, faster speeds, and miniaturization of electronic components has been increasing, driving the fabrication processes of semiconductor devices to evolve toward higher integration density. Consequently, patterns in highly scaled, highly integrated semiconductor devices may feature fine line widths and may be spaced apart with fine pitches.

The photolithography process is routinely used for forming fine patterns on semiconductor devices. In the photolithography process, a photosensitive polymer (e.g., a photoresist) is deposited on a substrate, selectively exposed to light using a mask pattern, dissolved in a developer, and developed to form the desired pattern. Photoresists may be classified as either positive or negative types. In the negative type, the exposed region becomes resistant to the developer, so that the exposed region remains after development to form the photoresist pattern. The photoresist pattern may act to protect the substructure during the subsequent etching process. However, in negative-type photoresist processes, the lower portion of the photoresist pattern may be exposed narrower than the upper portion of the photoresist pattern, which may cause an undercut phenomenon, leading to further issues.

First, as the aspect ratio of the photoresist pattern increases, the mechanical strength weakens, increasing the risk of the pattern tilting or collapsing during subsequent processes. Second, when etching with an undercut photoresist pattern, the etch profile becomes defective, making it difficult to achieve the intended shape. Third, if the width of the lower pattern becomes narrower due to undercutting, the step coverage in subsequent processes may deteriorate.

### SUMMARY

Some embodiments consistent with the present disclosure provide a method for fabricating a semiconductor device that improves the reliability of a photoresist pattern by reducing an undercut phenomenon.

The objectives to be solved by some embodiments of the present disclosure are not limited to the objectives mentioned above, and other objectives may be clearly understood by one of ordinary skill in the art from the following description.

Some embodiments consistent with the present disclosure provide a method for fabricating a semiconductor device, comprising forming a lower layer including a metal element on an upper surface of a substrate, forming a photoresist layer on an upper surface of the lower layer, forming, by performing an exposure process on the photoresist layer, a first exposure region formed by exposing a portion of the photoresist layer, a non-exposure region in which the photoresist layer is not exposed, and a second exposure region formed by exposing a portion of the lower layer beneath the first exposure region, providing electrons emitted from the second exposure region to a portion of the non-exposure region adjacent to a sidewall of the first exposure region in a horizontal direction, forming a third exposure region being in contact with the sidewall of the first exposure region by exposing the portion of the non-exposure region to which the electrons are provided, and forming a photoresist pattern including the first exposure region and the third exposure region by etching the non-exposure region, wherein a width of an upper surface of the first exposure region in the horizontal direction is greater than a width of a bottom surface of the first exposure region in the horizontal direction.

Some embodiments consistent with the present disclosure provide a method for fabricating a semiconductor device, comprising forming a mask layer on an upper surface of a substrate, forming a lower layer on an upper surface of the mask layer, forming a photoresist layer on an upper surface of the lower layer, forming, by performing an exposure process on the photoresist layer, a first exposure region formed by exposing a portion of the photoresist layer, a non-exposure region in which the photoresist layer is not exposed, and a second exposure region formed by exposing a portion of the lower layer beneath the first exposure region, providing electrons emitted from the second exposure region to a portion of the non-exposure region adjacent to a sidewall of the first exposure region in a horizontal direction, forming a third exposure region being in contact with the sidewall of the first exposure region by exposing the portion of the non-exposure region to which the electrons are provided, forming a photoresist pattern including the first exposure region and the third exposure region by etching the non-exposure region, forming a mask pattern by etching the mask layer using the photoresist pattern as a mask, and etching the substrate using the mask pattern as a mask.

Some embodiments consistent with the present disclosure provide a method for fabricating a semiconductor device, comprising forming a mask layer on an upper surface of a substrate, forming a lower layer including a metal element on an upper surface of the mask layer, forming a photoresist layer on an upper surface of the lower layer, forming, by performing an exposure process on the photoresist layer, a first exposure region formed by exposing a portion of the photoresist layer, a non-exposure region in which the photoresist layer is not exposed, and a second exposure region formed by exposing a portion of the lower layer beneath the first exposure region, providing electrons emitted from the second exposure region to a portion of the non-exposure region adjacent to a sidewall of the first exposure region in a horizontal direction, forming a third exposure region being in contact with the sidewall of the first exposure region by exposing the portion of the non-exposure region to which the electrons are provided, forming a photoresist pattern including the first exposure region and the third exposure region by etching the non-exposure region, forming a mask pattern by etching the mask layer using the photoresist pattern as a mask, and etching the substrate using the mask pattern as a mask, wherein a width of an upper surface of the first exposure region in the horizontal direction is greater than a width of a bottom surface of the first exposure region in the horizontal direction, wherein a slope profile of a sidewall of the third exposure region being in contact with the non-exposure region is different from a slope profile of the sidewall of the first exposure region, and wherein at least a portion of the third exposure region overlaps with the first exposure region in a vertical direction.

### BRIEF DESCRIPTION OF THE DRAWINGS

The accompanying drawings are included to provide a further understanding of disclosed example embodiments, and are incorporated in and constitute a part of this specification. In the drawings:

FIGS. 1 to 9 show schematic illustrations of intermediate stages of an example semiconductor device fabrication method, consistent with some embodiments of the present disclosure. FIG. 5 shows a schematic of an enlarged view of the R1 region of FIG. 4;

FIG. 10 shows a schematic illustration of an intermediate stage of an example semiconductor device fabrication method, consistent with some embodiments of the present disclosure.

FIG. 11 shows a schematic of an enlarged view of the R2 region of FIG. 10, consistent with some embodiments of the present disclosure.

FIG. 12 shows a schematic illustration of an intermediate stage of an example semiconductor device fabrication method, consistent with some embodiments of the present disclosure.

FIG. 13 shows a schematic of an enlarged view of the R3 region of FIG. 12, consistent with some embodiments of the present disclosure.

FIG. 14 shows a schematic il lustration of an intermediate stage of an example semiconductor device fabrication method, consistent with some embodiments of the present disclosure.

FIG. 15 shows a schematic of an enlarged view of the R4 region of FIG. 14, consistent with some embodiments of the present disclosure.

FIG. 16 shows a schematic illustration of an intermediate stage of an example semiconductor device fabrication method, consistent with some embodiments of the present disclosure.

FIG. 17 shows a schematic of an enlarged view of the R5 region of FIG. 16;

FIG. 18 shows a schematic illustration of an intermediate stage of an example semiconductor device fabrication method, consistent with some embodiments of the present disclosure.

FIG. 19 shows a schematic of an enlarged view of the R6 region of FIG. 18, consistent with some embodiments of the present disclosure.

FIGS. 20 to 26 show schematic illustrations of intermediate stages of an example semiconductor device fabrication method, consistent with some embodiments of the present disclosure.

### DETAILED DESCRIPTION

Example embodiments of the present disclosure will now be described more fully with reference to the accompanying drawings, in which example embodiments are shown. The same reference numerals are used for the same components in the drawings, and redundant descriptions thereof are omitted.

As used herein, a horizontal direction may include a first horizontal direction (X direction) and a second horizontal direction (Y direction) that intersect each other. A direction intersecting the first horizontal direction (X direction) and the second horizontal direction (Y direction) may be referred to as a vertical direction (Z direction). As used herein, a vertical level may be referred to as a height level according to a vertical direction (Z direction) of an arbitrary configuration.

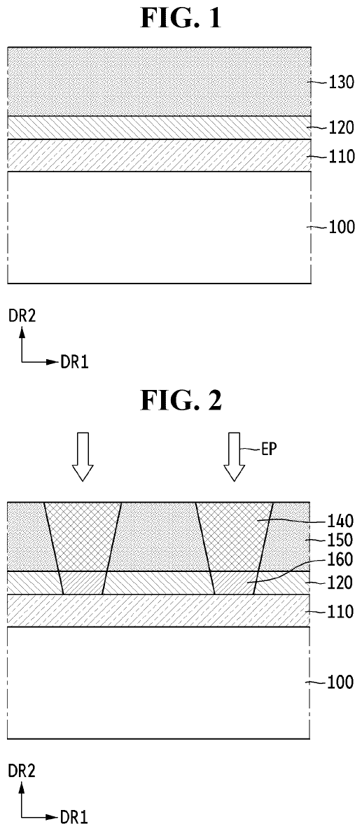

Referring to FIG. 1, a mask layer 110, a lower layer 120, and a photoresist layer 130 may be sequentially formed on the upper surface of a substrate 100.

As used herein, the substrate 100 refers to a structure on which fine patterns may be formed through a patterning process. For example, the substrate 100 may be bulk silicon or silicon-on-insulator (SOI). The substrate 100 may be a silicon substrate, or it may include other materials, for example, silicon germanium, gallium arsenide, silicon germanium on insulator (SGOI), indium antimonide, lead telluride compounds, indium arsenide, indium phosphide, gallium arsenide, or gallium antimonide. In some embodiments, the substrate 100 may be a substrate having an epitaxial layer formed on a base substrate, or may be a ceramic substrate, a quartz substrate, a glass substrate for a display, among other materials. In some embodiments, the substrate 100 may include insulating materials or conductive materials. In other words, the substrate 100 may not be limited as long as it is a surface on which fine patterns may be formed through a patterning process.

Hereinafter, the horizontal direction DR1 may be a direction parallel to the upper surface of the substrate 100 and the vertical direction DR2 may be a direction perpendicular to the horizontal direction DR1. In other words, the vertical direction DR2 may be a direction perpendicular to the upper surface of the substrate 100.

The mask layer 110 may be formed on the upper surface of the substrate 100. The mask layer 110 may be in contact with the upper surface of the substrate 100. For example, the mask layer 110 may be formed on the substrate 100 through a coating process such as, but not limited to, a spin coating process, dip coating process, or spray coating. For example, the mask layer 110 may include, but is not limited to, one or more of silicon oxide (SiO₂), silicon nitride (SiN), silicon oxynitride (SiON), silicon carbide (SiC), silicon oxycarbide (SiOC), silicon carbonitride (SiCN), or silicon oxycarbonitride (SiOCN). In some embodiments, the mask layer 110 may be a polymer layer including one or more of carbon (C) atoms, hydrogen (H) atoms, or oxygen (O) atoms.

The lower layer 120 may be formed on the upper surface of the mask layer 110. The lower layer 120 may be in contact with the upper surface of the mask layer 110. In some embodiments, the lower layer 120 may be conformally formed. The lower layer 120 may include metallic elements such as, but not limited to, tungsten (W), aluminum (Al), copper (Cu), cobalt (Co), titanium (Ti), tantalum (Ta), nickel (Ni), platinum (Pt), niobium (Nb), rhodium (Rh), palladium (Pd), iridium (Ir), osmium (Os), silver (Ag), gold (Au), zinc (Zn), or vanadium (V). In some embodiments, the lower layer 120 may include an alloyed form of one or more of metals including, but not limited to, tungsten (W), aluminum (Al), copper (Cu), cobalt (Co), titanium (Ti), tantalum (Ta), nickel (Ni), platinum (Pt), niobium (Nb), rhodium (Rh), palladium (Pd), iridium (Ir), osmium (Os), silver (Ag), gold (Au), zinc (Zn), or vanadium (V). In some embodiments, the lower layer 120 may include one or more of metal oxides, metal nitrides, metal oxynitrides, metal carbides, metal oxycarbides, metal carbonitrides, or metal oxycarbonitrides, containing one or more of the above-mentioned metals. In some embodiments, the lower layer 120 may include an organic material containing one or more of tungsten (W), aluminum (Al), copper (Cu), cobalt (Co), titanium (Ti), tantalum (Ta), nickel (Ni), platinum (Pt), niobium (Nb), rhodium (Rh), palladium (Pd), iridium (Ir), osmium (Os), silver (Ag), gold (Au), zinc (Zn), or vanadium (V), or an inorganic material containing one or more of tungsten (W), aluminum (Al), copper (Cu), cobalt (Co), titanium (Ti), tantalum (Ta), nickel (Ni), platinum (Pt), niobium (Nb), rhodium (Rh), palladium (Pd), iridium (Ir), osmium (Os), silver (Ag), gold (Au), zinc (Zn), or vanadium (V).

The photoresist layer 130 may be placed on the upper surface of the lower layer 120. The photoresist layer 130 may be in contact with the upper surface of the lower layer 120. For example, the photoresist layer 130 may be formed on the lower layer 120 using a suitable technique including, but not limited to, chemical vapor deposition (CVD), spin coating, PECVD (Plasma Enhanced CVD), or HDP-CVD (High Density Plasma CVD), or the like.

Referring to FIG. 2, an exposure process EP may be performed on the photoresist layer 130 (see FIG. 1) and the lower layer 120. For example, the exposure process EP may be performed using extreme ultraviolet (EUV) radiation. By performing the exposure process EP, a portion of the photoresist layer 130 (see FIG. 1) may be exposed to the EUV radiation to form the first exposure region 140. The first exposure region 140 may be spaced apart in the horizontal direction DR1 to form multiple exposure regions. In some embodiments, the width of the upper surface of the first exposure region 140 in the horizontal direction DR1 may be greater than the width of the bottom surface of the first exposure region 140 in the horizontal direction DR1. In other words, the first exposure region comprises non-parallel sidewalls. In the context of this disclosure, non-parallel sidewalls refer to sidewalls that are not parallel to each other, or sidewalls (e.g., the vertical surfaces of a structure) that are not perpendicular to a horizontal surface. For example, after the exposure process EP is performed, the unexposed portions of photoresist layer 130 (see FIG. 1) may be defined as the non-exposure region 150.

In some embodiments, by performing the exposure process EP, a portion of the lower layer 120 may be exposed to form a second exposure region 160. In other words, the second exposure region 160 may be formed inside the lower layer 120. A portion of the lower layer 120 exposed to the EUV radiation by the exposure process EP may be exposed to form a second exposure region 160. The second exposure region 160 may be formed beneath the first exposure region 140. In other words, the second exposure region 160 may overlap with the first exposure region 140 in the vertical direction DR2. The upper surface of the second exposure region 160 may be in contact with the bottom surface of the first exposure region 140. In some embodiments, the width of the upper surface of the second exposure region 160 in the horizontal direction DR1 may be larger than the width of the bottom surface of the second exposure region 160 in the horizontal direction DR1.

In FIG. 2, the sidewall of the second exposure region 160 is shown to have a continuous slope profile with the sidewall of the first exposure region 140, but the present disclosure is not limited thereto. In some exemplary embodiments, the sidewall of the second exposure region 160 may protrude in the horizontal direction DR1 more than the sidewall of the first exposure region 140. In other words, at least a portion of the second exposure region 160 may overlap with the non-exposure region 150 in the vertical direction DR2.

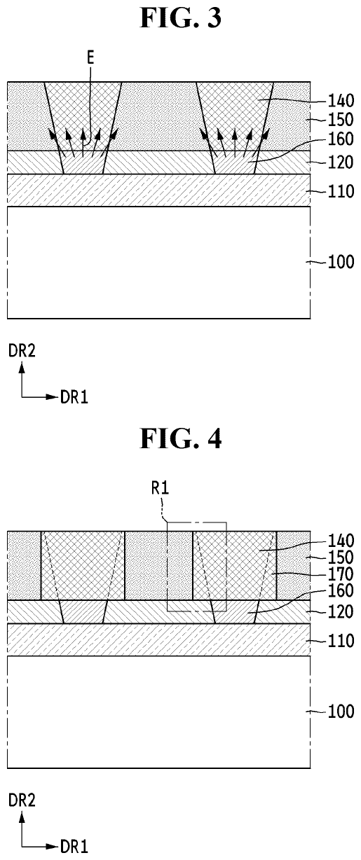

Referring to FIG. 3, the second exposure region 160 which is formed by being exposed to EUV radiation by the exposure process EP (see FIG. 2) may absorb energy from high-energy EUV photons and emit electrons (E). The electrons (E) emitted from the second exposure region 160 may be provided to the first exposure region 140 and to a portion of the non-exposure region 150 adjacent to the sidewall of the first exposure region 140 in a horizontal direction DR1.

Reference is now made to FIG. 4, which illustrates a schematic of an intermediate stage of a semiconductor device fabrication, consistent with some embodiments of the present disclosure. A portion of the non-exposure region 150 provided with electrons (E) (see FIG. 3) emitted from the second exposure region 160 may be exposed to form the third exposure region 170. In other words, the electrons (E) emitted from the second exposure region 160 upon interaction of EUV radiation with the second exposure region 160 may interact with a portion of the non-exposure region 150 to form the third exposure region 170.

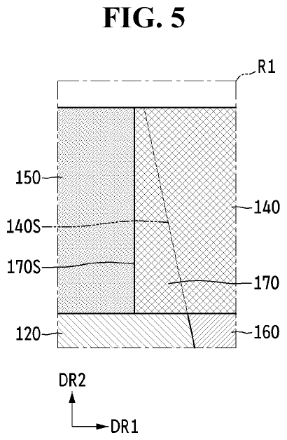

Referring to FIG. 5, which shows a cross-sectional enlarged view of region R1 of FIG. 4, consistent with some embodiments of the present disclosure. In some embodiments, the third exposure region 170 may be formed on the sidewall 140S of the first exposure region 140. A portion of the third exposure region 170 may be in contact with the sidewall 140S of the first exposure region 140 and another portion of the third exposure region 170 may be in contact with the non-exposure region 150, as illustrated in FIG. 5. The third exposure region 170 may be formed between the sidewall 140S of the first exposure region 140 and the non-exposure region 150. In some embodiments, the first exposure region 140 may be spaced apart and separated from the non-exposure region 150 in the horizontal direction DR1 by the third exposure region 170. In other words, the sidewall 140S of the first exposure region 140 is not in contact with the non-exposure region 150.

The third exposure region 170 may include a sidewall 170S in contact with the non-exposure region 150. In some embodiments, the slope profile of the sidewall 170S of the third exposure region 170, which is in contact with the non-exposure region 150, may be different from the slope profile of the sidewall 140S of the first exposure region 140. For example, the sidewall 170S of the third exposure region 170 may have a constant slope profile. In some embodiments, the sidewall 170S of the third exposure region 170 may be parallel or substantially parallel with respect to the vertical direction DR2. In this context, “substantially parallel” with respect to the vertical direction DR2 indicates that the angle between the slope of an edge of a region and the vertical direction DR2 is negligibly small, for example, less than ±2°, such that the edge of the region is non-convergent or non-divergent with the vertical direction DR2. In some embodiments, the bottom surface of the third exposure region 170 may be formed on the same plane as the bottom surface of the first exposure region 140. In other words, the bottom surface of the third exposure region 170 and the bottom surface of the first exposure region 140 may be coplanar. In this context, “coplanar” refers to points, lines, or surfaces that lie on the same plane. A plane is a flat, two-dimensional surface that extends infinitely in all directions. The width of the third exposure region 170 in the horizontal direction DR1 closer to the upper surface of the lower layer 120 may be larger than the width in the horizontal direction DR1 closer to the upper surface of first exposure region 140. In some embodiments, the uppermost surface of the third exposure region 170 may be formed on the same plane as the upper surface of the first exposure region 140, but the present disclosure is not limited thereto.

At least a portion of the third exposure region 170 may overlap with the first exposure region 140 in the vertical direction DR2. In FIGS. 4 and 5, the bottom surface of the third exposure region 170 is shown as not being in contact with the upper surface of the second exposure region 160, but the present disclosure is not limited thereto. In some embodiments, at least a portion of the bottom surface of the third exposure region 170 may overlap with or be in contact with the upper surface of the second exposure region 160.

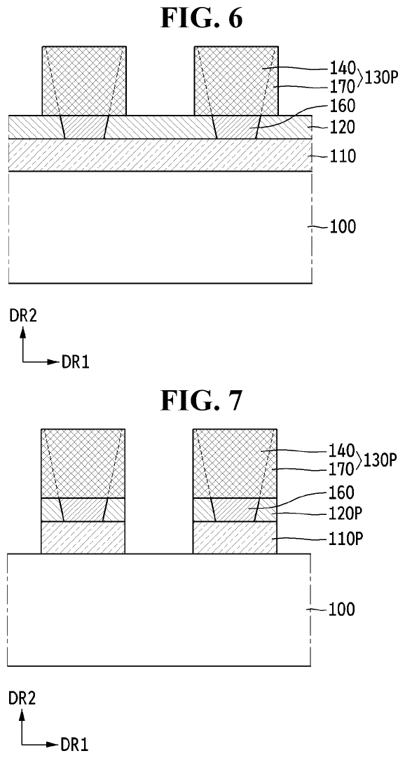

Referring to FIG. 6, the non-exposure region 150 (see FIGS. 4 and 5) may be etched away using a developer. This allows a photoresist pattern 130P including the first exposure region 140 and the third exposure region 170 to be formed on each of the upper surface of the lower layer 120 and the second exposure region 160.

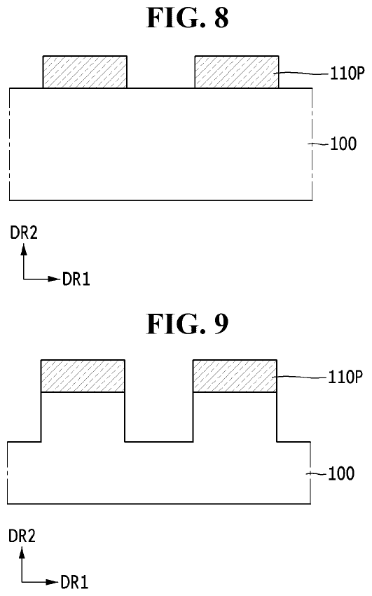

Referring to FIG. 7 and FIG. 8, the lower layer 120 (see FIG. 6) may be etched using the photoresist pattern 130P as a mask. After this etching process is completed, the remaining lower layer 120 (see FIG. 6) may be defined as the lower pattern 120P. In other words, the lower pattern 120P may be formed by etching the lower layer 120 (see FIG. 6) using the photoresist pattern 130P as a mask. The second exposure region 160 may be formed inside the lower pattern 120P. The second exposure region 160 and the lower pattern 120P may overlap with the photoresist pattern 130P in the vertical direction DR2.

Subsequently, the mask layer 110 (see FIG. 6) may be etched using the photoresist pattern 130P and the lower pattern 120P as masks. After completing this etching process, the remaining mask layer 110 (see FIG. 6) may be defined as a mask pattern 110P. In other words, the mask pattern 110P may be formed by etching the mask layer 110 (see FIG. 6) using the photoresist pattern 130P and the lower pattern 120P as masks. Subsequently, as shown in FIG. 8, the photoresist pattern 130P and the lower pattern 120P and the second exposure region 160 may be etched.

Referring to FIG. 7, it is shown that after the mask pattern 110P is formed, the photoresist pattern 130P remains on the upper surface of the lower pattern 120P, but the present disclosure is not limited thereto. In some embodiments, the photoresist pattern 130P may be etched while the mask pattern 110P is being formed. Alternatively, in some embodiments, the photoresist pattern 130P, the lower pattern 120P, and the second exposure region 160 may be etched while the mask pattern 110P is being formed (not shown).

Referring to FIG. 9, a portion of the substrate 100 may be etched using the mask pattern 110P as a mask. Through this etching process, a fine pattern may be formed beneath the mask pattern 110P inside the substrate 100.

In a method for fabricating a semiconductor device according to some embodiments of the present disclosure, a lower layer 120 containing a metal element may be formed beneath the photoresist layer 130, and a second exposure region 160 may be formed inside the lower layer 120 while an exposure process EP is being performed on the photoresist layer 130. The second exposure region 160 may emit electrons (E) to expose a portion of the non-exposure region 150 adjacent to the first exposure region 140 to form a third exposure region 170. In subsequent processes, a mask pattern 110P may be formed using the photoresist pattern 130P, which includes the first exposure region 140 and the third exposure region 170, as a mask, and a portion of the substrate 100 may be etched using the mask pattern 110P as a mask.

In a method for fabricating a semiconductor device according to some embodiments of the present disclosure, a third exposure region 170 may be formed on the sidewall of the first exposure region 140 using electrons (E) emitted from the second exposure region 160 formed inside the lower layer 120. The closer to the bottom surface of the first exposure region 140, the higher the thickness of the third exposure region 170 in the horizontal direction DR1 may be formed. Accordingly, the method for fabricating a semiconductor device according to some embodiments of the present disclosure may reduce the undercut phenomenon in which the lower portion of the photoresist pattern 130P is formed narrower than the upper portion of the photoresist pattern 130P, thereby improving the reliability of the photoresist pattern 130P.

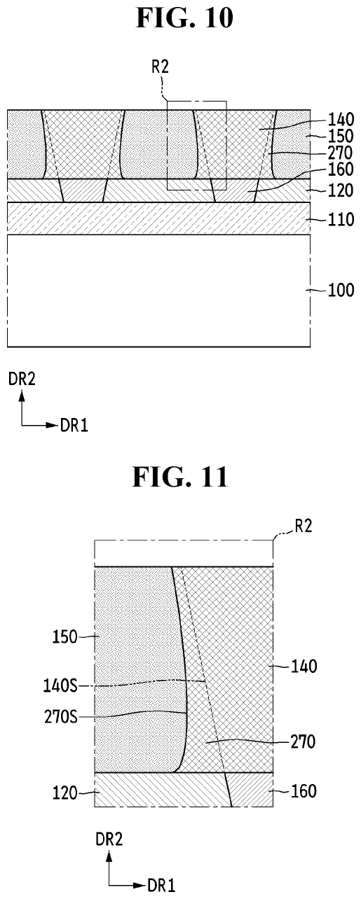

Hereinafter, a method for fabricating a semiconductor device according to some embodiments of the present disclosure is described with reference to FIGS. 10 and 11. The description will focus on the differences from the method for fabricating the semiconductor device shown in FIGS. 1 to 9.

FIG. 10 illustrates a schematic of an intermediate stage of a method for fabricating a semiconductor device, consistent with some embodiments of the present disclosure. FIG. 11 illustrates an enlarged view of the R2 region of FIG. 10.

Referring to FIGS. 10 and 11, in the method for fabricating a semiconductor device according to some embodiments of the present disclosure, after performing the fabrication processes shown in FIGS. 1 to 3, a portion of the non-exposure region 150 provided with the electrons (E) (see FIG. 3) emitted from the second exposure region 160 may be exposed to form the fourth exposure region 270. The fourth exposure region 270 may be formed on the sidewall 140S of the first exposure region 140. The fourth exposure region 270 may be in contact with the sidewall 140S of the first exposure region 140. The fourth exposure region 270 may be formed between the sidewall 140S of the first exposure region 140 and the non-exposure region 150.

Referring to FIG. 11, in some embodiments, the slope profile of the sidewall 270S of the fourth exposure region 270 that is in contact with the non-exposure region 150 may be different from the slope profile of the sidewall 140S of the first exposure region 140. For example, the sidewall 270S of the third exposure region 270 that is in contact with the non-exposure region 150 may be formed in a concave shape toward the sidewall 140S of the first exposure region 140. In such a case, the width of the fourth exposure region 270 in the horizontal direction DR1 closer to the upper surface of the lower layer 120 may be larger than the width of the fourth exposure region 270 in the horizontal direction DR1 closer to the upper surface of the first exposure region 140. The uppermost surface of the third exposure region 270 may be formed on the same plane as the upper surface of the first exposure region 140. After formation of the sidewall 270S, the fabrication processes shown in FIGS. 6 to 9 may be performed.

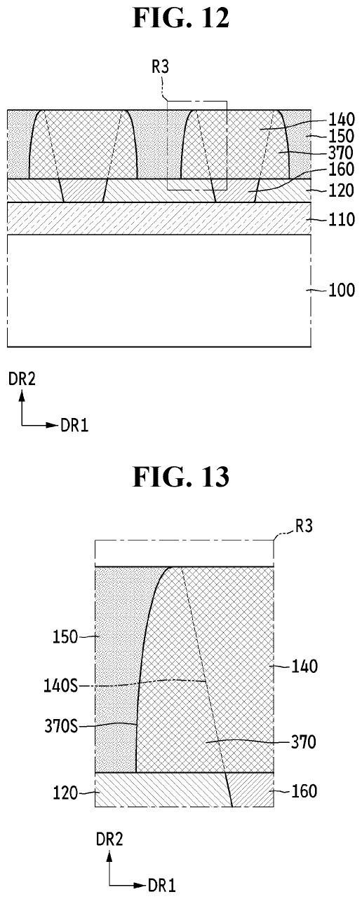

Hereinafter, a method for fabricating a semiconductor device according to some embodiments of the present disclosure is described with reference to FIGS. 12 and 13. The description will focus on the differences from the method for fabricating the semiconductor device shown in FIGS. 1 to 9.

FIG. 12 illustrates a schematic of an intermediate stage of a method for fabricating a semiconductor device, consistent with some embodiments of the present disclosure. FIG. 13 illustrates an enlarged view of the R3 region of FIG. 12.

Referring to FIG. 12 and FIG. 13, in the method for fabricating a semiconductor device according to some embodiments of the present disclosure, after performing the fabrication processes shown in FIGS. 1 to 3, a portion of the non-exposure region 150 provided with electrons (E) (see FIG. 3) emitted from the second exposure region 160 may be exposed to form the fifth exposure region 370. The fifth exposure region 370 may be formed on the sidewall 140S of the first exposure region 140. The fifth exposure region 370 may be in contact with the sidewall 140S of the first exposure region 140. The fifth exposure region 370 may be formed between the sidewall 140S of the first exposure region 140 and the non-exposure region 150.

Referring to FIG. 13, in some embodiments, the slope profile of the sidewall 370S of the fifth exposure region 370 that is in contact with the non-exposure region 150 may be different from the slope profile of the sidewall 140S of the first exposure region 140. For example, the sidewall 370S of the third exposure region 370 that is in contact with the non-exposure region 150 may be formed in a convex shape toward the non-exposure region 150. In such a case, the width of the fifth exposure region 370 in the horizontal direction DR1 closer to the upper surface of the lower layer 120 may be larger than the width of the fifth exposure region 370 in the horizontal direction DR1 closer to the upper surface of the first exposure region 140. The uppermost surface of the fifth exposure region 370 may be formed on the same plane as the upper surface of the first exposure region 140. After formation of the sidewall 370S, the fabrication processes shown in FIGS. 6 to 9 may be performed.

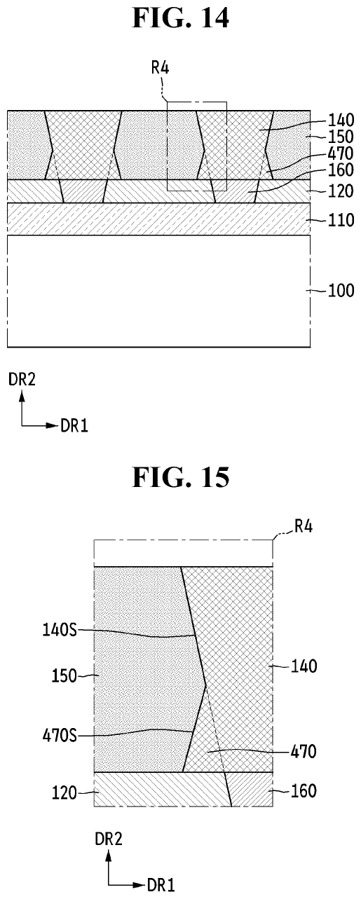

Hereinafter, a method for fabricating a semiconductor device according to some embodiments of the present disclosure is described with reference to FIGS. 14 and 15. The description will focus on the differences from the method for fabricating the semiconductor device shown in FIGS. 1 to 9.

FIG. 14 illustrates a schematic of an intermediate stage of a method for fabricating a semiconductor device, consistent with some embodiments of the present disclosure. FIG. 15 illustrates an enlarged view of the R4 region of FIG. 14.

Referring to FIGS. 14 and 15, in a method for fabricating a semiconductor device according to some embodiments of the present disclosure, after performing the fabrication process shown in FIGS. 1 to 3, a portion of the non-exposure region 150 provided with the electrons (E) (see FIG. 3) emitted from the second exposure region 160 may be exposed to form the sixth exposure region 470. For example, the sixth exposure region 470 may be formed on the sidewall 140S of the first exposure region 140. The sixth exposure region 470 may be in contact with the sidewall 140S of the first exposure region 140. The sixth exposure region 470 may be formed between the sidewall 140S of the first exposure region 140 and the non-exposure region 150. For example, at least a portion of the sidewall 140S of the first exposure region 140 may be in contact with the non-exposure region 150 on the sixth exposure region 470. In other words, a portion of the sidewall 140S of the first exposure region 140 may be in contact with the sixth exposure region 470, and the remaining portion of the sidewall 140S of the first exposure region 140 may be in contact with the non-exposure region 150.

Referring to FIG. 15, in some embodiments, the slope profile of the sidewall 470S of the sixth exposure region 470 that is in contact with the non-exposure region 150 may be different from the slope profile of the sidewall 140S of the first exposure region 140. For example, the sidewall 470S of the sixth exposure region 470 that is in contact with the non-exposure region 150 may have a continuous slope profile. The width of the sixth exposure region 470 in the horizontal direction DR1 closer to the upper surface of the lower layer 120 may be larger than the width of the sixth exposure region 470 in the horizontal direction DR1 closer to the upper surface of the first exposure region 140. The uppermost surface of the sixth exposure region 470 may be formed lower than the upper surface of the first exposure region 140. After formation of the sidewall 470S, the fabrication processes shown in FIGS. 6 to 9 may be performed.

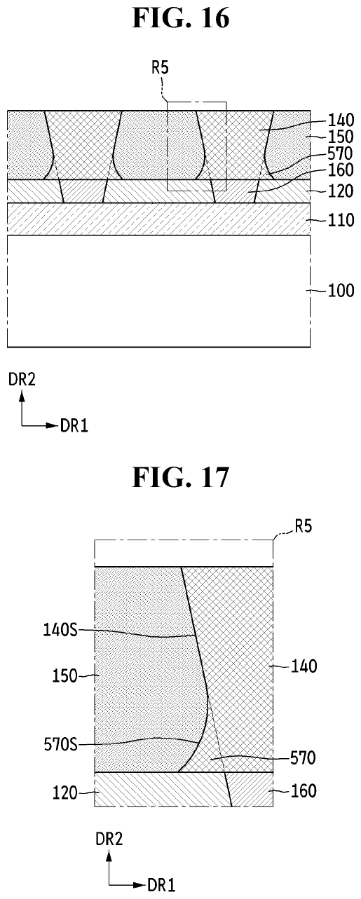

Hereinafter, a method for fabricating a semiconductor device according to some embodiments of the present disclosure is described with reference to FIGS. 16 and 17. The description will focus on the differences from the method for fabricating the semiconductor device shown in FIGS. 1 to 9.

FIG. 16 illustrates a schematic of an intermediate stage of a method for fabricating a semiconductor device, consistent with some embodiments of the present disclosure. FIG. 17 illustrates an enlarged view of the R5 region of FIG. 16.

Referring to FIG. 16 and FIG. 17, in a method for fabricating a semiconductor device according to some embodiments of the present disclosure, after performing the fabrication process shown in FIGS. 1 to 3, a portion of the non-exposure region 150 provided with the electrons (E) (see FIG. 3) emitted from the second exposure region 160 may be exposed to form the seventh exposure region 570. For example, the seventh exposure region 570 may be formed on the sidewall 140S of the first exposure region 140. The seventh exposure region 570 may be in contact with the sidewall 140S of the first exposure region 140. The seventh exposure region 570 may be formed between the sidewall 140S of the first exposure region 140 and the non-exposure region 150. In some embodiments, at least a portion of the sidewall 140S of the first exposure region 140 on the third exposure region 570 may be in contact with the non-exposure region 150. In other words, a portion of the sidewall 140S of the first exposure region 140 may be in contact with the seventh exposure region 570, and the remaining portion of the sidewall 140S of the first exposure region 140 may be in contact with the non-exposure region 150.

Referring to FIG. 17, in some embodiments, the slope profile of the sidewall 570S of the seventh exposure region 570 that is in contact with the non-exposure region 150 may be different from the slope profile of the sidewall 140S of the first exposure region 140. The sidewall 570S of the seventh exposure region 570 that is in contact with the non-exposure region 150 may be formed in a concave shape toward the sidewall 140S of the first exposure region 140. The width of the seventh exposure region 470 in the horizontal direction DR1 closer to the upper surface of the lower layer 120 may be larger than the width of the seventh exposure region 470 in the horizontal direction DR1 closer to the upper surface of the first exposure region 140. The uppermost surface of the seventh exposure region 570 may be formed lower than the upper surface of the first exposure region 140. After formation of the sidewall 570S, the fabrication processes shown in FIGS. 6 to 9 may be performed.

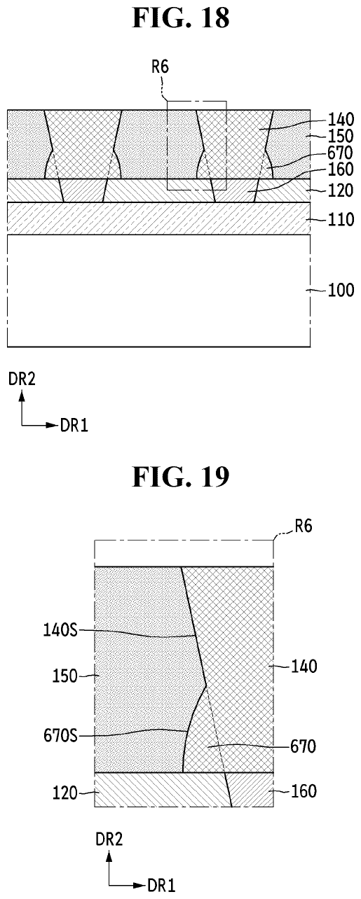

Hereinafter, a method for fabricating a semiconductor device according to some embodiments of the present disclosure is described with reference to FIGS. 18 and 19. The description will focus on the differences from the method for fabricating the semiconductor device shown in FIGS. 1 to 9.

FIG. 18 illustrates a schematic of an intermediate stage of a method for fabricating a semiconductor device, consistent with some embodiments of the present disclosure. FIG. 19 illustrates an enlarged view of the R6 region of FIG. 18.

Referring to FIGS. 18 and 19, in the method for fabricating a semiconductor device according to some embodiments of the present disclosure, after performing the fabrication processes shown in FIGS. 1 to 3, a portion of the non-exposure region 150 provided with the electrons (E) (see FIG. 3) emitted from the second exposure region 160 may be exposed to form the eighth exposure region 670. For example, the eighth exposure region 670 may be formed on the sidewall 140S of the first exposure region 140. The eighth exposure region 670 may be in contact with the sidewall 140S of the first exposure region 140. The eighth exposure region 670 may be formed between the sidewall 140S of the first exposure region 140 and the non-exposure region 150. For example, at least a portion of the sidewall 140S of the first exposure region 140 may be in contact with the non-exposure region 150 on the eighth exposure region 670. In other words, a portion of the sidewall 140S of the first exposure region 140 may be in contact with the eighth exposure region 670, and the remaining portion of the sidewall 140S of the first exposure region 140 may be in contact with the non-exposure region 150.

Referring to FIG. 19, in some embodiments, the slope profile of the sidewall 670S of the eighth exposure region 670 that is in contact with the non-exposure region 150., may be different from the slope profile of the sidewall 140S of the first exposure region 140. For example, the sidewall 670S of the eighth exposure region 670 that is in contact with the non-exposure region 150 may be formed in a convex shape toward the non-exposure region 150. The width of the eighth exposure region 470 in the horizontal direction DR1 closer to the upper surface of the lower layer 120 may be larger than the width of the eighth exposure region 470 in the horizontal direction DR1 closer to the upper surface of the first exposure region 140. The uppermost surface of the eighth exposure region 670 may be formed lower than the upper surface of the first exposure region 140. After formation of the sidewall 670S, the fabrication processes shown in FIGS. 6 to 9 may be performed.

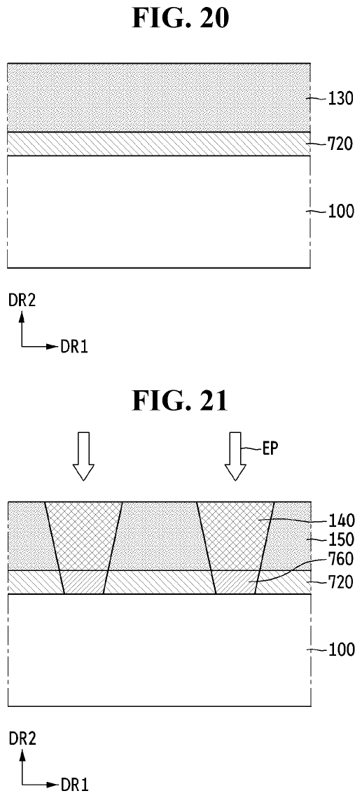

Hereinafter, a method for fabricating a semiconductor device according to some embodiments of the present disclosure is described with reference to FIGS. 20 to 26. The differences from the method for fabricating the semiconductor device shown in FIGS. 1 to 9 will be described in detail.

FIGS. 20 to 26 are schematic illustrations of intermediate stages for explaining a method for fabricating a semiconductor device, consistent with some embodiments of the present disclosure.

Referring to FIG. 20, a lower layer 720 and a photoresist layer 130 may be sequentially formed on the upper surface of substrate 100. The lower layer 720 may be formed on the upper surface of the substrate 100. The lower layer 720 may be in contact with the upper surface of the substrate 100. The lower layer 720 may include the same material as the lower layer 120 shown in FIG. 1. The photoresist layer 130 may be disposed on the upper surface of the lower layer 720. The photoresist layer 130 may be in contact with the upper surface of the lower layer 720.

Referring to FIG. 21, an exposure process EP may be performed on the photoresist layer 130 (see FIG. 20) and on the lower layer 720. For example, the exposure process EP may be performed using EUV radiation. By performing the exposure process EP, a portion of the photoresist layer 130 (see FIG. 20) may be exposed to form a first exposure region 140. The first exposure region 140 may be spaced apart in the horizontal direction DR1 to form multiple regions. In some embodiments, the width of the upper surface of the first exposure region 140 in the horizontal direction DR1 may be greater than the width of the bottom surface of the first exposure region 140 in the horizontal direction DR1. After the exposure process EP is performed, the unexposed photoresist layer 130 (see FIG. 20) may be referred to as the non-exposure region 150.

In some embodiments, by performing the exposure process EP, a portion of the lower layer 720 may be exposed to form a second exposure region 760. In other words, the second exposure region 760 may be formed inside the lower layer 720. For example, a portion of the lower layer 720 exposed to EUV radiation by the exposure process EP may be exposed to form the second exposure region 760. The second exposure region 760 may be formed beneath the first exposure region 140. In other words, the second exposure region 760 may overlap with the first exposure region 140 in the vertical direction DR2. The upper surface of the second exposure region 760 may be in contact with the bottom surface of the first exposure region 140. The width of the upper surface of the second exposure region 760 in the horizontal direction DR1 may be greater than the width of the bottom surface of the second exposure region 760 in the horizontal direction DR1.

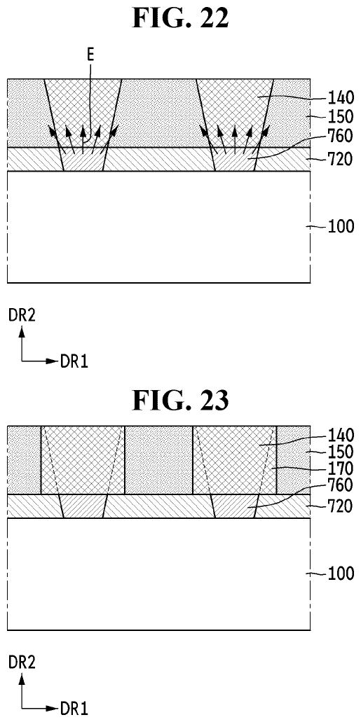

Referring to FIG. 22, the second exposure region 760 formed by being exposed to EUV radiation through the exposure process EP (see FIG. 21) may absorb energy from high-energy EUV photons and emit electrons (E). For example, electrons (E) emitted from the second exposure region 760 may interact with the first exposure region 140 and a portion of the non-exposure region 150 adjacent to the sidewall of the first exposure region 140 in the horizontal direction DR1.

Referring to FIG. 23, a portion of the non-exposure region 150 interacting with electrons (E) (see FIG. 22) emitted from the second exposure region 760 may be exposed to form a third exposure region 170. The third exposure region 170 may be formed on the sidewall of the first exposure region 140. The third exposure region 170 may be in contact with the sidewall of the first exposure region 140. The third exposure region 170 may be formed between the sidewall of the first exposure region 140 and the non-exposure region 150.

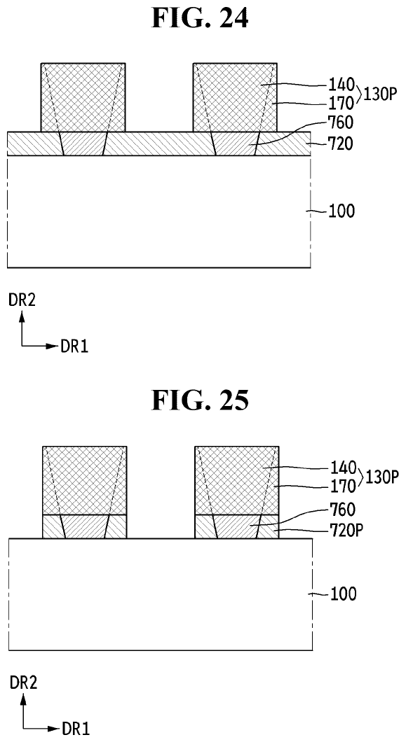

Referring to FIG. 24, the non-exposure region 150 (see FIG. 23) may be etched using a developer. This allows a photoresist pattern 130P including the first exposure region 140 and the third exposure region 170 to be formed on the upper surfaces of the lower layer 720 and the second exposure region 760, respectively.

Referring to FIG. 25, the lower layer 720 (see FIG. 24) may be etched using the photoresist pattern 130P as a mask. After this etching process is completed, the remaining lower layer 720 (see FIG. 24) may be defined as the lower pattern 720P. In other words, the lower pattern 720P may be formed by etching the lower layer 720 (see FIG. 24) using the photoresist pattern 130P as a mask. In some embodiments, the second exposure region 760 may be formed inside the lower pattern 720P. The second exposure region 760 and the lower pattern 720P may overlap with the photoresist pattern 130P in the vertical direction DR2. In FIG. 25, although it is shown that the photoresist pattern 130P remains on the upper surface of the lower pattern 720P after the lower pattern 720P is formed, the present disclosure is not limited thereto. In some embodiments, the photoresist pattern 130P may be etched while the lower pattern 720P is being formed.

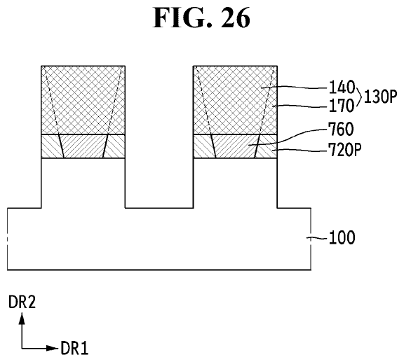

Referring to FIG. 26, a portion of the substrate 100 may be etched using the lower pattern 720P and the photoresist pattern 130P as a mask. Through this etching process, a fine pattern may be formed beneath the lower pattern 720P inside the substrate 100.

Although exemplary embodiments have been described, the present disclosure should not be limited to these embodiments, but various changes and modifications can be made by one ordinary skilled in the art within the spirit and scope of the present disclosure as hereinafter claimed.

What is claimed is:

1. A method for fabricating a semiconductor device comprising:
forming a lower layer including a metal element on an upper surface of a substrate;
forming a photoresist layer on an upper surface of the lower layer;
forming, by performing an exposure process on the photoresist layer, a first exposure region formed by exposing a portion of the photoresist layer, a non-exposure region in which the photoresist layer is not exposed, and a second exposure region formed by exposing a portion of the lower layer beneath the first exposure region;
providing electrons emitted from the second exposure region to a portion of the non-exposure region adjacent to a sidewall of the first exposure region in a horizontal direction;
forming a third exposure region being in contact with the sidewall of the first exposure region by exposing the portion of the non-exposure region to which the electrons are provided; and
forming a photoresist pattern including the first exposure region and the third exposure region by etching the non-exposure region,
wherein a width of an upper surface of the first exposure region in the horizontal direction is greater than a width of a bottom surface of the first exposure region in the horizontal direction.

2. The method of claim 1, wherein a width of the third exposure region in the horizontal direction increases as it becomes closer to the upper surface of the lower layer.

3. The method of claim 1, wherein a bottom surface of the third exposure region is formed on the same plane as the bottom surface of the first exposure region.

4. The method of claim 1, wherein a slope profile of a sidewall of the third exposure region being in contact with the non-exposure region is different from a slope profile of the sidewall of the first exposure region.

5. The method of claim 1, wherein at least a portion of the third exposure region overlaps with the first exposure region in a vertical direction.

6. The method of claim 1, wherein forming the lower layer on the upper surface of the substrate comprises:
forming a mask layer on the upper surface of the substrate; and
forming the lower layer on an upper surface of the mask layer.

7. The method of claim 6, further comprising, after forming the photoresist pattern:
forming a mask pattern by etching the mask layer using the photoresist pattern as a mask; and
etching the substrate using the mask pattern as a mask.

8. The method of claim 1, wherein forming the third exposure region being in contact with the sidewall of the first exposure region comprises:
forming the third exposure region between the sidewall of the first exposure region and the non-exposure region, and the sidewall of the first exposure region being not in contact with the non-exposure region.

9. The method of claim 1, wherein forming the third exposure region being in contact with the sidewall of the first exposure region comprises:
forming the third exposure region between the sidewall of the first exposure region and the non-exposure region, and at least a portion of the sidewall of the first exposure region being in contact with the non-exposure region.

10. The method of claim 1, wherein an uppermost surface of the third exposure region is formed lower than the upper surface of the first exposure region.

11. The method of claim 1, wherein forming the third exposure region being in contact with the sidewall of the first exposure region comprises:
forming a sidewall of the third exposure region being in contact with the non-exposure region as concave toward the sidewall of the first exposure region.

12. The method of claim 1, wherein forming the third exposure region being in contact with the sidewall of the first exposure region comprises:
forming a sidewall of the third exposure region being in contact with the non-exposure region as convex toward the non-exposure region.

13. A method for fabricating a semiconductor device, comprising:
forming a mask layer on an upper surface of a substrate;
forming a lower layer on an upper surface of the mask layer;
forming a photoresist layer on an upper surface of the lower layer;
forming, by performing an exposure process on the photoresist layer, a first exposure region formed by exposing a portion of the photoresist layer, a non-exposure region in which the photoresist layer is not exposed, and a second exposure region formed by exposing a portion of the lower layer beneath the first exposure region;
providing electrons emitted from the second exposure region to a portion of the non-exposure region adjacent to a sidewall of the first exposure region in a horizontal direction;
forming a third exposure region being in contact with the sidewall of the first exposure region by exposing the portion of the non-exposure region to which the electrons are provided;
forming a photoresist pattern including the first exposure region and the third exposure region by etching the non-exposure region;
forming a mask pattern by etching the mask layer using the photoresist pattern as a mask; and
etching the substrate using the mask pattern as a mask.

14. The method of claim 13, wherein a width of an upper surface of the first exposure region in the horizontal direction is greater than a width of a bottom surface of the first exposure region in the horizontal direction.

15. The method of claim 13, wherein a slope profile of a sidewall of the third exposure region being in contact with the non-exposure region is different from a slope profile of the sidewall of the first exposure region.

16. The method of claim 13, wherein at least a portion of the third exposure region overlaps with the first exposure region in a vertical direction.

17. The method of claim 13, wherein forming the mask pattern by etching the mask layer comprises:
forming the lower pattern by etching the lower layer using the photoresist pattern as a mask.

18. The method of claim 13, wherein forming the third exposure region being in contact with the sidewall of the first exposure region comprises:
forming the third exposure region between the sidewall of the first exposure region and the non-exposure region, and the sidewall of the first exposure region being not in contact with the non-exposure region.

19. The method of claim 13, wherein an uppermost surface of the third exposure region is formed lower than an upper surface of the first exposure region.

20. A method for fabricating a semiconductor device, comprising:
forming a mask layer on an upper surface of a substrate;
forming a lower layer including a metal element on an upper surface of the mask layer;
forming a photoresist layer on an upper surface of the lower layer;
forming, by performing an exposure process on the photoresist layer, a first exposure region formed by exposing a portion of the photoresist layer, a non-exposure region in which the photoresist layer is not exposed, and a second exposure region formed by exposing a portion of the lower layer beneath the first exposure region;
providing electrons emitted from the second exposure region to a portion of the non-exposure region adjacent to a sidewall of the first exposure region in a horizontal direction;
forming a third exposure region being in contact with the sidewall of the first exposure region by exposing the portion of the non-exposure region to which the electrons are provided;
forming a photoresist pattern including the first exposure region and the third exposure region by etching the non-exposure region;
forming a mask pattern by etching the mask layer using the photoresist pattern as a mask; and
etching the substrate using the mask pattern as a mask,
wherein a width of an upper surface of the first exposure region in the horizontal direction is greater than a width of a bottom surface of the first exposure region in the horizontal direction,
wherein a slope profile of a sidewall of the third exposure region being in contact with the non-exposure region is different from a slope profile of the sidewall of the first exposure region, and
wherein at least a portion of the third exposure region overlaps with the first exposure region in a vertical direction.
